(19) United States
(12) Patent Application Publication
(10) Pub. No.: US 2026/0023110 A1
(43) Pub. Date: Jan. 22, 2026

(54) VOLTAGE CALIBRATION CIRCUIT, SEMICONDUCTOR PACKAGE STRUCTURE AND VOLTAGE CALIBRATION METHOD

(71) Applicant: Realtek Semiconductor Corporation, Hsinchu (TW)

(72) Inventor: Kang Ming TIEN, Hsinchu (TW)

(21) Appl. No.: 19/257,451

(22) Filed: Jul. 1, 2025

(30) Foreign Application Priority Data
Jul. 22, 2024 (TW) 113127335

(51) Int. Cl. G01R 31/28; G01R 17/02

(52) U.S. Cl. CPC G01R 31/2879; G01R 31/2896; G01R 17/02

(57) ABSTRACT

A voltage calibration circuit arranged in a chip and comprising a voltage monitor circuit, a calibration circuit and a storage circuit is provided. The voltage monitor circuit is coupled to at least one power management unit of the chip and configured to: calculate a voltage-code graph based on a received reference voltage and a received divided voltage; and output at least one output code based on the voltage-code graph and at least one output voltage received from the power management unit(s). The calibration circuit is coupled to the voltage monitor circuit and the power management unit(s), and configured to receive the output code(s) and adjust an output level of the power management unit(s) based on the output code(s) and a target code. The storage circuit is coupled to the calibration circuit, and configured to store the voltage-code graph and the output level of the power management unit(s).

### RELATED APPLICATIONS

This application claims priority to Taiwan Application Serial Number 113127335, filed on Jul. 22, 2024, which is herein incorporated by reference in its entirety.

### BACKGROUND

### Technical Field

The present disclosure relates to output voltage calibrations by a power management unit (PMU). More particularly, the present disclosure relates to a voltage calibration circuit, a semiconductor package structure and a voltage calibration method configured to calibrate the output voltage of a power management unit.

### Description of Related Art

Today's Wifi systems usually have built-in power management units (e.g., DC-DC converter (DCDC), low-dropout regulator (LDO) and other voltage regulators), which are used to output voltages to each sub-block to perform each function in a chip. In order to ensure that these power management units can accurately output voltages, the output voltages are often calibrated by the devices in the production line with customized specific patterns.

However, with different power management units, the patterns used by the devices for calibration will also be different. In addition, since not all types of power management units have pin headers connected to the package, some power management units can only perform voltage screening during the circuit probing (CP) stage. These conditions limit the flexibility and efficiency of the device during calibration. Moreover, since the calibration voltages of the power management units are easily affected by the printed circuit boards (PCB), relays and sockets, IR drop may occurs, resulting in inaccurate calibration. Therefore, how to effectively improve the flexibility and accuracy of the output voltage calibration is one of the topics in this field.

### SUMMARY

A voltage calibration circuit is provided in the present disclosure. The voltage calibration circuit comprises a voltage monitor circuit, a calibration circuit and a storage circuit. The voltage monitor circuit is coupled to at least one power management unit of a first chip and configured to: in a circuit probing stage, receive a reference voltage and a divided voltage, and calculate a voltage-code graph based on the reference voltage and the divided voltage; and in a function test stage, receive at least one output voltage from the at least one power management unit, and generate at least one output code based on the at least one output voltage and the voltage-code graph. The calibration circuit is coupled to the voltage monitor circuit and the at least one power management unit, and is configured to receive the at least one output code from the voltage monitor circuit and adjust an output level of the at least one power management unit based on the at least one output code and a target code, in the function test stage. The storage circuit is coupled to the calibration circuit, and is configured to store the voltage-code graph and the output level of the at least one power management unit.

A semiconductor package structure is provided in the present disclosure. The semiconductor package structure comprises a first chip. The first chip comprises at least one power management unit and a voltage calibration circuit. The at least one power management unit is configured to receive a reference voltage from a reference source and generate at least one output voltage. The voltage calibration circuit comprises a voltage monitor circuit, a calibration circuit and a storage circuit. The voltage monitor circuit is coupled to at least one power management unit and configured to: in a circuit probing stage, receive the reference voltage and a divided voltage, and calculate a voltage-code graph based on the reference voltage and the divided voltage; and in a function test stage, receive the at least one output voltage from the at least one power management unit, and generate at least one output code based on the at least one output voltage and the voltage-code graph. The calibration circuit is coupled to the voltage monitor circuit and the at least one power management unit, and is configured to receive the at least one output code from the voltage monitor circuit and adjust an output level of the at least one power management unit based on the at least one output code and a target code, in the function test stage. The storage circuit is coupled to the calibration circuit, and is configured to store the voltage-code graph and the output level of the at least one power management unit.

A voltage calibration method is provided in the present disclosure. The voltage calibration method is suitable for a semiconductor package structure comprising a first chip, wherein the first chip comprises at least one power management unit and a voltage calibration circuit. The voltage calibration method comprises: receiving, by a voltage monitor circuit of the voltage calibration circuit, a reference voltage and a divided voltage, in a circuit probing stage; calculating, by the voltage monitor circuit, a voltage-code graph based on the reference voltage and the divided voltage, in the circuit probing stage; receiving, by the voltage monitor circuit, at least one output voltage from the at least one power management unit, in a function test stage; generating, by the voltage monitor circuit, at least one output code based on the at least one output voltage and the voltage-code graph, in the function test stage; adjusting, by a calibration circuit of the voltage calibration circuit, an output level of the at least one power management unit based on the at least one output code and a target code, in the function test stage; and storing, by a storage circuit of the voltage calibration circuit, the voltage-code graph and the output level of the at least one power management unit.

With the voltage calibration circuit, the semiconductor package structure and the voltage calibration method in the present disclosure, the voltage calibration can be performed in a package without specific patterns provided by devices, thereby improving the flexibility and efficiency of voltage calibrations. Furthermore, the semiconductor package structure and the voltage calibration method in the present disclosure can mitigate the IR drop in circuits during voltage calibrations, thereby improving the accuracy of voltage calibrations.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows.

FIG. 1 is a functional block diagram of a semiconductor package structure in accordance with some embodiments of the present disclosure.

FIG. 2 is a functional block diagram of a chip in accordance with some embodiments of the present disclosure.

FIG. 3A is a schematic diagram of the relationship between voltages detected by a voltage monitor circuit and codes in accordance with some embodiments of the present disclosure.

FIG. 3B is a schematic diagram of the relationship between voltages detected by a voltage monitor circuit and codes in accordance with some embodiments of the present disclosure.

FIG. 3C is a schematic diagram of the relationship between output voltages and output levels in accordance with some embodiments of the present disclosure.

FIG. 4 is a functional block diagram of a semiconductor package structure in accordance with some embodiments of the present disclosure.

FIG. 5 is a flowchart of a voltage calibration method in accordance with some embodiments of the present disclosure.

### DETAILED DESCRIPTION

Reference will now be made in detail to the present embodiments of the disclosure, examples of which are illustrated in the accompanying drawings.

In the present disclosure, when an element is referred to as “connected”, it may mean “electrically connected” or “optically connected”. When an element is referred to as “coupled”, it may mean “electrically coupled” or “optically coupled”. “Connected” or “coupled” can also be used to indicate that two or more components operate or interact with each other. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

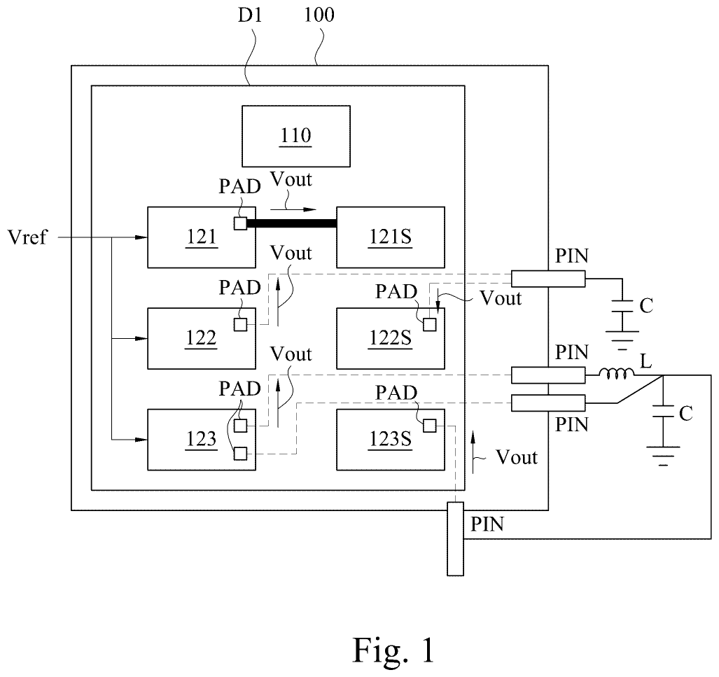

FIG. 1 is a functional block diagram of a semiconductor package structure 100 in accordance with some embodiments of the present disclosure. In some embodiments, the semiconductor package structure 100 comprises a chip D1 and a plurality of pin headers PIN. The chip D1 comprises a voltage calibration circuit and at least one power management unit (PMU), and is configured to receive a reference voltage Vref from an external power source and generate an output voltage Vout.

Taking the embodiment of FIG. 1 as an example, the chip D1 comprises a voltage calibration circuit 110 and power management units 121-123. In some embodiments, each of the power management units 121-123 can be implemented with a low dropout regulator (LDO), a capless LDO, a switch regulator (SWR), other similar components or a combination of the aforementioned elements.

In some embodiments, the chip D1 further comprises sub-blocks (or refer to as management sub-units) 121S, 122S and 123S. The sub-blocks 121S, 122S and 123S are respectively connected to the power management units 121-123 through different paths, so as to receive the output voltages Vout from the power management units 121-123, thereby performing functions of the sub-blocks.

Specifically, as shown in FIG. 1, when a power management unit is implemented with a capless LDO (e.g., the power management unit 121), a pad PAD of the power management unit will be connected to the sub-block 121S by routing (marked with a solid line in the figure) in the chip D1. When a power management unit is implemented with a LDO (e.g., the power management unit 122), a pad PAD of the power management unit will be connected to a pin header PIN of the semiconductor package structure 100 by bonding (marked with dotted lines in the figure), and then connected to a pad PAD of the sub-block 122S by bonding. When a power management unit is implemented with a SWR (e.g., the power management unit 123), two pads PAD of the power management unit will be connected to two pin headers PIN of the semiconductor package structure 100 by bonding, and then connected to a pad PAD of the sub-block 123S through another pin header PIN by bonding.

In addition, in some embodiments, when a power management unit is implemented with a LDO (e.g., the power management unit 122), in order to maintain the stable operation of the LDO, the pin header PIN connected to the LDO may be coupled to an external capacitor C, and this external capacitor C is coupled to ground.

On the other hand, in some embodiments, when a power management unit is implemented with a SWR (e.g., the power management unit 123), in order to maintain the stable operation of the SWR, among the two pin headers PIN connected to the SWR, one pin header PIN will be coupled to a first terminal of an external inductor L, and the other pin header PIN will be coupled to a second terminal of the external inductor L (for transmitting a feedback voltage back to the SWR), coupled to another pin header PIN of the sub-block 123S (for transmitting the output voltage Vout to the sub-block 123S), and coupled to another external capacitor C, wherein this external capacitor C is coupled to ground.

It should be noted that although the chip D1 is illustrated as a chip with three power management units and three sub-blocks in FIG. 1, the present disclosure is not limited to this. Chips with other types and amounts of power management units and sub-blocks are within the scope of the present disclosure. In some embodiments, the chip D1 may comprise only the power management units 121-122 and the sub-blocks 121S and 122S. In other embodiments, the chip D1 may comprise five power management units and five sub-blocks.

It should be noted that for the sake of brevity of the figure, the connection relationship between the voltage calibration circuit 110 and the power management units 121-123, the sub-blocks 121S-123S is not shown in FIG. 1. In some embodiments, the voltage calibration circuit 110 is coupled to a portion of the power management units 121-123 at which the output voltages Vout are transmitted (i.e., the pads PAD), and is coupled to a portion of the sub-blocks 121S-123S at which the output voltages Vout are received (i.e., routing nodes or the pads PAD), so as to detect whether the output voltages Vout transmitted by the power management units 121-123 and the output voltages Vout received by the sub-blocks 121S-123S are abnormal or not.

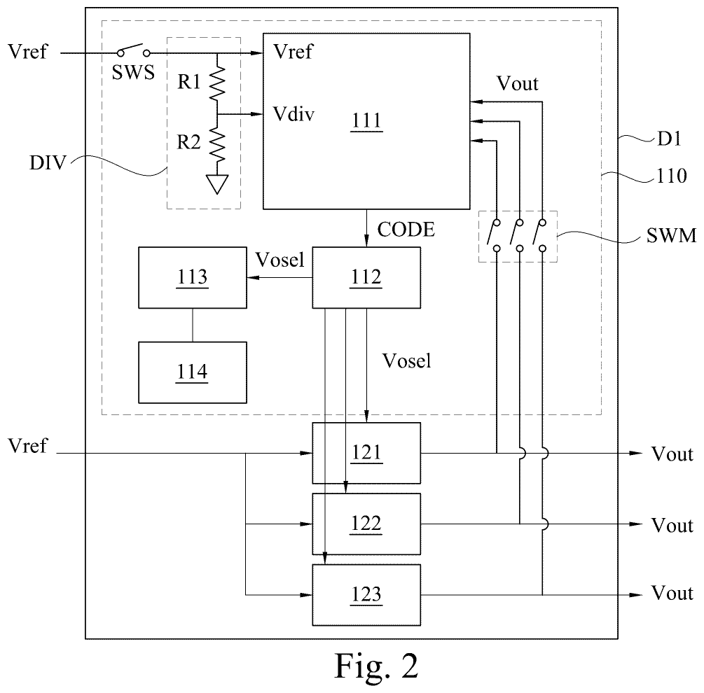

Regarding the internal structure of the voltage calibration circuit 110 and the connection relationship with other components, please further refer to FIG. 2. FIG. 2 is a functional block diagram of the chip D1 in accordance with some embodiments of the present disclosure. It should be noted that for the sake of brevity of the figure, the sub-blocks 121S-123S are omitted in FIG. 2.

In some embodiments, the voltage calibration circuit 110 comprises a divider circuit DIV, a voltage monitor circuit 111, a calibration circuit 112 and a storage circuit 113. The divider circuit DIV is coupled to the voltage monitor circuit 111, and is configured to receive the reference voltage Vref from an external power source and generate a divided voltage Vdiv to the voltage monitor circuit 111 based on the reference voltage Vref. Specifically, the divider circuit DIV comprises resistors R1 and R2 coupled between a input terminal of the divider circuit DIV and the ground in series, and the node between the resistors R1 and R2 is coupled to the voltage monitor circuit 111. After receiving the reference voltage Vref, the divider circuit DIV will generate the corresponding divided voltage Vdiv based on the ratio between the resistances of the resistors R1 and R2, and then transmit the divided voltage Vdiv to the voltage monitor circuit 111.

The voltage monitor circuit 111 is coupled to the divider circuit DIV, the calibration circuit 112, the power management units 121-123 and sub-blocks 121S-123S (not shown). In some embodiments, when the chip D1 is in a circuit probing (CP) stage, the voltage monitor circuit 111 is configured to receive the reference voltage Vref and the divided voltage Vdiv, and calculate a voltage-code graph based on the reference voltage Vref and the divided voltage Vdiv.

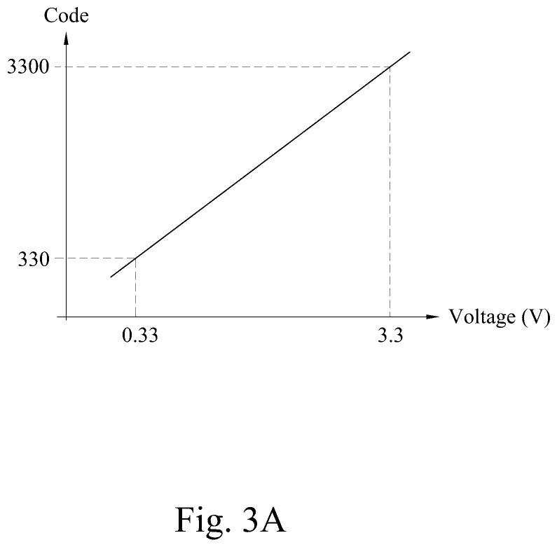

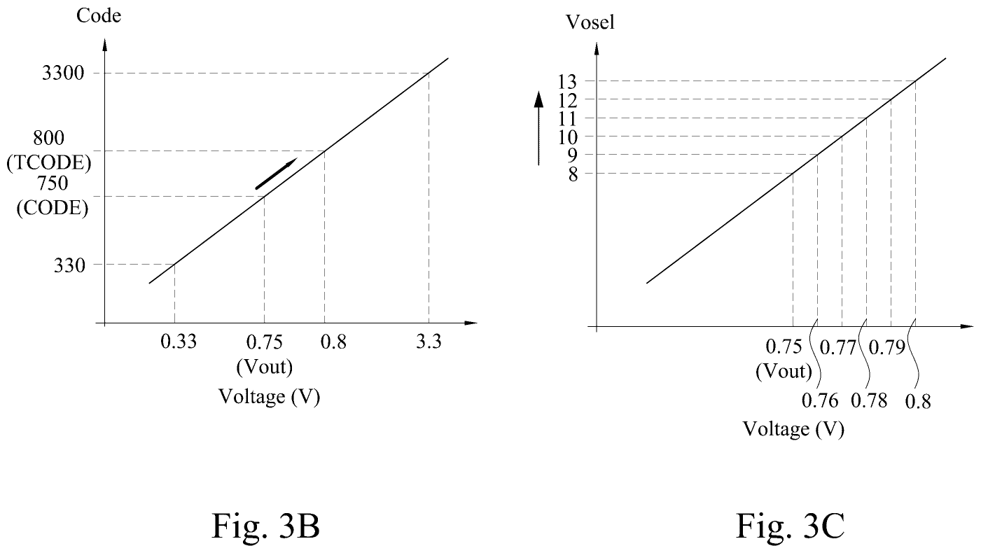

Regarding the voltage-code graph calculated by the voltage monitor circuit 111, please further refer to FIG. 3A. FIG. 3A is a schematic diagram of the relationship between voltages detected by the voltage monitor circuit 111 and codes in accordance with some embodiments of the present disclosure. In operation, first, the voltage monitor circuit 111 receives a reference voltage Vref of 3.3 volt, and sets 3.3 volts to be corresponding to a specific code (e.g., the code 3300 shown in FIG. 3A). Next, the voltage monitor circuit 111 receives the divided voltage Vdiv and set another corresponding code based on the divided voltage Vdiv. Taking the embodiment of FIG. 3A as an example, when the ratio between the resistances of the resistors R1 and R2 is set to 9:1, the voltage monitor circuit 111 will set the code corresponding to the received divided voltage Vdiv (e.g., 0.33 volts) to one-tenth of the code corresponding to the reference voltage Vref (e.g., one-tenth of the code 3300, which is 330). Finally, based on the reference voltage Vref, the divided voltage Vdiv and their respective corresponding codes, the voltage monitor circuit 111 can calculate the voltage-code graph as shown in FIG. 3A.

Please refer to FIG. 2 again. When the chip D1 ends the CP stage and enters a function test (FT) stage, the voltage monitor circuit 111 will receive a plurality of output voltages Vout from the power management units 121-123. At this time, the voltage monitor circuit 111 can calculate output codes CODE corresponding to the output voltages Vout through interpolation based on the voltage-code graph (and the output voltages Vout) calculated in the CP stage, and transmit the output codes CODE to the calibration circuit 112 for subsequent calibrations.

The calibration circuit 112 is coupled to the voltage monitor circuit 111, the storage circuit 113 and the power management units 121-123, and is configured to receive the output codes CODE from the voltage monitor circuit 111, and adjust an output level of the power management units 121-123 based on the output codes CODE and a target code TCODE, in the FT stage. Regarding the detailed method of the calibration circuit 112 calibrating the power management units 121-123, please refer to the following paragraphs.

The storage circuit 113 is coupled to the calibration circuit 112 and is configured to store the voltage-code graph calculated by the voltage monitor circuit 111 in the CP stage, and store the output levels Vosel to which the calibration circuit 112 adjusts the power management units 121-123 in the FT stage. In some embodiments, the storage circuit 113 is a non-volatile memory, such as a read-only memory (ROM), a flash memory, a non-volatile random-access memory (NVRAM), other similar memories or a combination of the aforementioned elements.

In some embodiments, the chip D1 further comprises a reading unit 114 coupled to the storage circuit 113 and configured to read the data stored in storage circuit 113 (i.e., the voltage-code graph and the output levels of the power management units 121-123).

In some embodiments, the chip D1 further comprises a source switch circuit SWS and a monitor switch circuit SWM. The source switch circuit SWS is coupled between an input terminal of the chip D1 (i.e., the terminal configured to receive the reference voltage Vref) and the voltage monitor circuit 111, configured to be turned on in the CP stage to make the voltage monitor circuit 111 receive the reference voltage Vref and the divided voltage Vdiv for calculating the voltage-code graph, and configured to be turned off in the FT stage to prevent the voltage monitor circuit 111 from being interfered by the reference voltage Vref when receiving the output voltages Vout.

The monitor switch circuit SWM comprises a plurality of sub-switches. The plurality of sub-switches are respectively coupled between the power management units 121-123 and the voltage monitor circuit 111, configured to be turned on in the FT test stage to make the voltage monitor circuit 111 receive the output voltages Vout from the power management units 121-123, and configured to be turned off in the CP stage to prevent the voltage monitor circuit 111 from being interfered by the output voltages Vout when receiving the reference voltage Vref.

Regarding the detailed method of the calibration circuit 112 adjusting the output levels Vosel of the power management units 121-123, please refer to FIG. 2, FIG. 3B and FIG. 3C together. FIG. 3B is a schematic diagram of the relationship between voltages detected by the voltage monitor circuit 111 and codes in accordance with some embodiments of the present disclosure. FIG. 3C is a schematic diagram of the relationship between the output voltages Vout and the output levels Vosel in accordance with some embodiments of the present disclosure.

In the embodiment of FIG. 3B, the target code TCODE is set to 800. When one of the output voltages Vout received by the voltage monitor circuit 111 is 0.75 volts, the voltage monitor circuit 111 will determine that the output code CODE corresponding to this output voltage Vout is 750 according to the voltage-code graph. Since the output code CODE at this time is smaller than the target code TCODE, the calibration circuit 112 will determine that the output level Vosel of the power management unit (that outputs this output voltage Vout) needs to be raised.

In the embodiment of FIG. 3C, the output voltage Vout of 0.75 volts is corresponding to the output level Vosel of 8. When the calibration circuit 112 raises the output level Vosel of a power management unit to 9, the voltage monitor circuit 111 will detect the output voltage Vout of this power management unit again and generate a corresponding output code CODE again, and the calibration circuit 112 will determine whether the output code CODE matches the target code TCODE again. If the output code CODE is still smaller than the target code TCODE, the calibration circuit 112 will raise the output level Vosel of this power management unit again, until the output code CODE matches the target code TCODE.

On the contrary, when the output code CODE is greater than the target code TCODE, the calibration circuit 112 will determine that the output level Vosel of the power management unit needs to be lowered. The process of lowering the output level Vosel of the power management unit and re-judging is similar to the aforementioned process of the output code CODE being smaller than the target code TCODE, and thus the details will not be repeated here.

When the output code CODE is equal to the target code TCODE, the storage circuit 113 is configured to store the output levels Vosel of the power management units 121-123.

It should be noted that the target code TCODE of the present disclosure is not limited to a specific value. The target code TCODE with a specific value range is also within the scope of the present disclosure. In some embodiments, the target code TCODE can be a range within plus or minus 50 of a specific code. In other embodiments, the target code TCODE can be a range within plus or minus 10% of a specific code.

In some embodiments of the present disclosure, the difference between adjacent output levels Vosel is 5 to 10 millivolts. Compared with the output level difference of 30 to 40 millivolts in the traditional voltage calibrations, the embodiment of the present disclosure can achieve finer calibration.

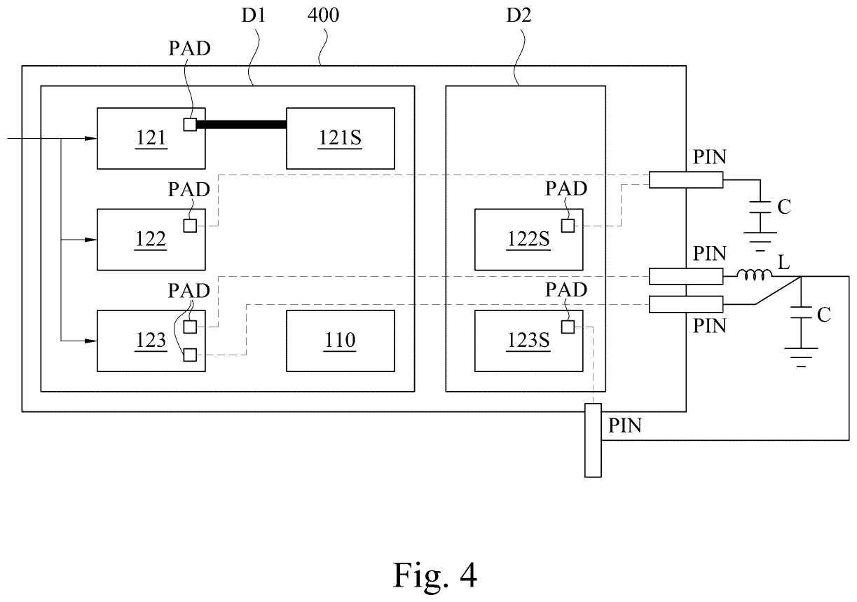

In some embodiments, as shown in FIG. 1, the semiconductor package structure 100 may be a system on a chip (SoC) structure. In other words, all of the power management units 121-123 are arranged on the chip D1. In other embodiments, the semiconductor package structure of the present disclosure may be a multi-die structure. Please refer to FIG. 4. FIG. 4 is a functional block diagram of a semiconductor package structure 400 in accordance with some embodiments of the present disclosure.

Similar to the semiconductor package structure 100 of FIG. 1, the semiconductor package structure 400 also comprises the voltage calibration circuit 110 and power management units 121-123. The difference is that the semiconductor package structure 400 comprises the chip D1 and a chip D2, wherein the sub-block 121S is arranged on the chip D1, but the sub-blocks 122S and 123S are arranged on the chip D2 instead of the chip D1. In addition, since the voltage calibration circuit 110 and the sub-blocks 122S, 123S are arranged on different chips, the voltage calibration circuit 110 is connected to the sub-blocks 122S and 123S by bonding (marked with dotted lines in the figure).

It should be noted that the configuration of the circuits of the semiconductor package structure 400 in FIG. 4 is only an example, and is not intended limit the present disclosure. Other configurations of the circuits of the semiconductor package structure 400 are within the scope of the present disclosure. In some embodiments, the semiconductor package structure 400 may comprise more than two chips, and a plurality of sub-blocks may be arranged in these chips.

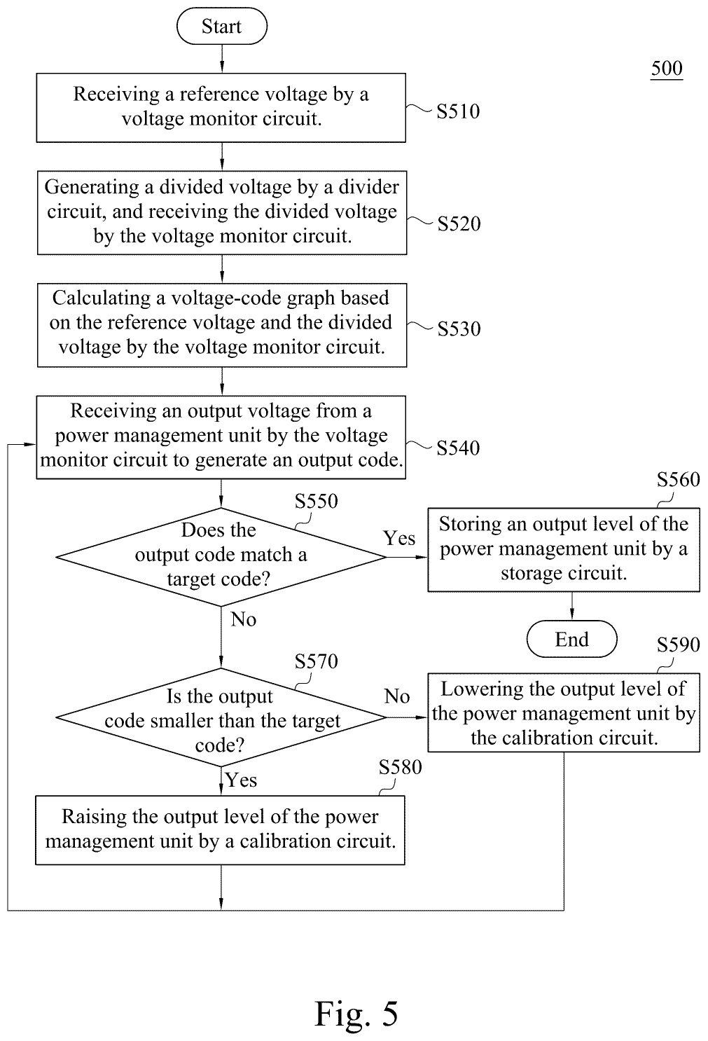

FIG. 5 is a flowchart of a voltage calibration method 500 in accordance with some embodiments of the present disclosure. In some embodiments, the voltage calibration method 500 comprises steps S510, S520, S530, S540, S550, S560, S570, S580 and S590.

In step S510, a voltage monitor circuit receives a reference voltage from an external power source. Next, step S520 will be performed. In step S520, a divider circuit generates a divided voltage based on the reference voltage and transmits the divided voltage to a voltage monitor circuit. Next, step S530 will be performed.

In step S530, the voltage monitor circuit calculates a voltage-code graph based on the received reference voltage and the received divided voltage, and stores the voltage-code graph in a storage circuit. Next, step S540 will be performed.

In step S540, the voltage monitor circuit receives output voltages from each power management unit, calculates corresponding output codes based on each output voltage and the voltage-code graph, and transmits the output codes to a calibration circuit. Next, step S550 will be performed.

In step S550, the calibration circuit determines whether each received output code matches (i.e., be equal to) a target code. When the output code matches the target code, step S560 will be performed next. When the output code does not match the target code, step S570 will be performed next.

In step S560, the storage circuit stores an output level of the power management unit, so as to finish the calibration of the power management unit.

In step S570, the calibration circuit determines whether the output code is smaller than the target code. When the output code is smaller than the target code, step S580 will be performed next. When the output code is not smaller than (i.e., greater than) the target code, step S590 will be performed next.

In step S580, the calibration circuit raises the output level Vosel of the power management unit. Next, step S540 will be performed again.

In step S590, the calibration circuit lowers the output level Vosel of the power management unit. Next, step S540 will be performed again.

It should be noted that the number and order of steps in the voltage calibration method 500 of the present disclosure are only examples, and are not intended to limit the present disclosure. Other numbers and orders of steps are within the scope of the present disclosure. In some embodiments, steps S510 and S520 can be performed synchronously.

With the semiconductor package structures 100, 400, the voltage calibration circuit 110 and the voltage calibration method 500 of the present disclosure, the output voltages of power management units can be directly calibrated inside the chip without additional devices for inputting patterns, thereby improving the flexibility and efficiency of voltage calibration. In addition, since the voltage calibration circuit and the power management units are connected through the routing or bonding inside the chip, compared with traditional voltage monitor methods, the calibration voltages of the present disclosure will not cause IR drop due to the influence of printed circuit boards (PCB), relays and sockets, thereby improving the accuracy of calibration.

As the complexity of the chip increases, the difficulty of packaging and bonding also increases. With the semiconductor package structures 100, 400, the voltage calibration circuit 110 and the voltage calibration method 500 of the present disclosure, the function of automatically detecting whether an abnormality occurs in the power path (e.g., the entire power path from the power management unit 122 through the pad PAD and pin header PIN to the sub-block 122S) can be realized, thereby increasing the efficiency of troubleshooting and improving the reliability of the chip.

The above are preferred embodiments of the present disclosure. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A voltage calibration circuit, arranged in a first chip and comprising:
a voltage monitor circuit, coupled to at least one power management unit of the first chip, and configured to:
in a circuit probing stage, receive a reference voltage and a divided voltage, and calculate a voltage-code graph based on the reference voltage and the divided voltage; and
in a function test stage, receive at least one output voltage from the at least one power management unit, and generate at least one output code based on the at least one output voltage and the voltage-code graph;
a calibration circuit, coupled to the voltage monitor circuit and the at least one power management unit, and configured to:
in the function test stage, receive the at least one output code from the voltage monitor circuit, and adjust an output level of the at least one power management unit based on the at least one output code and a target code; and
a storage circuit, coupled to the calibration circuit and configured to store the voltage-code graph and the output level of the at least one power management unit.

2. The voltage calibration circuit of claim 1, wherein when the at least one output code is smaller than the target code, the calibration circuit is configured to raise the output level of the at least one power management unit;
wherein when the at least one output code is greater than the target code, the calibration circuit is configured to lower the output level of the at least one power management unit; and
wherein when the at least one output code is equal to the target code, the storage circuit is configured to store the output level of the at least one power management unit.

3. The voltage calibration circuit of claim 1, further comprising:
a source switch circuit, coupled between a reference source and the voltage monitor circuit, configured to be turned on in the circuit probing stage to transmit the reference voltage to the voltage monitor circuit from the reference source, and configured to be turned off in the function test stage; and
a divider circuit, coupled between the source switch circuit and the voltage monitor circuit, and configured to generate the divided voltage based on the reference source and transmit the divided voltage to the voltage monitor circuit.

4. The voltage calibration circuit of claim 1, further comprising a monitor switch circuit, wherein the monitor switch circuit comprises at least one sub-switch, wherein the at least one sub-switch is respectively coupled between the at least one power management unit and the voltage monitor circuit, and configured to be turned off in the circuit probing stage and be turned on in the function test stage.

5. The voltage calibration circuit of claim 1, wherein the voltage monitor circuit is further coupled to at least one management sub-unit, wherein the at least one management sub-unit is respectively coupled to the at least one power management unit to respectively receive the at least one output voltage.

6. The voltage calibration circuit of claim 5, wherein at least one of the at least one management sub-unit is arranged in the first chip, and the others of the at least one management sub-unit is arranged in a second chip different from the first chip.

7. The voltage calibration circuit of claim 1, wherein the storage circuit is a non-volatile memory.

8. A semiconductor package structure, comprising:
a first chip, comprising:
at least one power management unit, configured to receive a reference voltage from a reference source and generate at least one output voltage, respectively; and
a voltage calibration circuit, comprising:
a voltage monitor circuit, coupled to the at least one power management unit and configured to:
in a circuit probing stage, receive the reference voltage and a divided voltage, and calculate a voltage-code graph based on the reference voltage and the divided voltage; and
in a function test stage, receive the at least one output voltage from the at least one power management unit, and generate at least one output code based on the at least one output voltage and the voltage-code graph;
a calibration circuit, coupled to the voltage monitor circuit and the at least one power management unit, and configured to:
in the function test stage, receive the at least one output code from the voltage monitor circuit, and adjust an output level of the at least one power management unit based on the at least one output code and a target code; and
a storage circuit, coupled to the calibration circuit and configured to store the voltage-code graph and the output level of the at least one power management unit.

9. The semiconductor package structure of claim 8, wherein when the at least one output code is smaller than the target code, the calibration circuit is configured to raise the output level of the at least one power management unit;
wherein when the at least one output code is greater than the target code, the calibration circuit is configured to lower the output level of the at least one power management unit; and
wherein when the at least one output code is equal to the target code, the storage circuit is configured to store the output level of the at least one power management unit.

10. The semiconductor package structure of claim 8, wherein the voltage calibration circuit further comprises:
a source switch circuit, coupled between the reference source and the voltage monitor circuit, configured to be turned on in the circuit probing stage to transmit the reference voltage to the voltage monitor circuit from the reference source, and configured to be turned off in the function test stage; and
a divider circuit, coupled between the source switch circuit and the voltage monitor circuit, and configured to generate the divided voltage based on the reference source and transmit the divided voltage to the voltage monitor circuit.

11. The semiconductor package structure of claim 8, wherein the voltage calibration circuit further comprises a monitor switch circuit, wherein the monitor switch circuit comprises at least one sub-switch, wherein the at least one sub-switch is respectively coupled between the at least one power management unit and the voltage monitor circuit, and configured to be turned off in the circuit probing stage and be turned on in the function test stage.

12. The semiconductor package structure of claim 8, wherein the voltage monitor circuit is further coupled to at least one management sub-unit, wherein the at least one management sub-unit is respectively coupled to the at least one power management unit to respectively receive the at least one output voltage.

13. The semiconductor package structure of claim 12, further comprising a second chip different from the first chip, wherein at least one of the at least one management sub-unit is arranged in the first chip, and the others of the at least one management sub-unit is arranged in the second chip.

14. The semiconductor package structure of claim 8, wherein the storage circuit is a non-volatile memory.

15. A voltage calibration method, suitable for a semiconductor package structure comprising a first chip, wherein the first chip comprises at least one power management unit and a voltage calibration circuit, wherein the voltage calibration method comprises:
receiving, by a voltage monitor circuit of the voltage calibration circuit, a reference voltage and a divided voltage, in a circuit probing stage;
calculating, by the voltage monitor circuit, a voltage-code graph based on the reference voltage and the divided voltage, in the circuit probing stage;
receiving, by the voltage monitor circuit, at least one output voltage from the at least one power management unit, in a function test stage;
generating, by the voltage monitor circuit, at least one output code based on the at least one output voltage and the voltage-code graph, in the function test stage;
adjusting, by a calibration circuit of the voltage calibration circuit, an output level of the at least one power management unit based on the at least one output code and a target code, in the function test stage; and
storing, by a storage circuit of the voltage calibration circuit, the voltage-code graph and the output level of the at least one power management unit.

16. The voltage calibration method of claim 15, wherein adjusting, by the calibration circuit of the voltage calibration circuit, the output level of the at least one power management unit based on the at least one output code and the target code comprises:
in response to the at least one output code being smaller than the target code, raising the output level of the at least one power management unit by the calibration circuit; and
in response to the at least one output code being greater than the target code, lowering the output level of the at least one power management unit by the calibration circuit.

17. The voltage calibration method of claim 15, wherein receiving, by the voltage monitor circuit of the voltage calibration circuit, the reference voltage and the divided voltage comprises:
turning on, by the voltage calibration circuit, a source switch circuit of the voltage calibration circuit, to transmit the reference voltage to the voltage monitor circuit from a reference source;
generating, by a divider circuit of the voltage calibration circuit, the divided voltage based on the reference source; and
transmitting, by the divider circuit, the divided voltage to the voltage monitor circuit.

18. The voltage calibration method of claim 15, wherein receiving, by the voltage monitor circuit, the at least one output voltage from the at least one power management unit comprises:
turning on, by the voltage calibration circuit, a monitor switch circuit of the voltage calibration circuit, to transmit the at least one output voltage to the voltage monitor circuit from the at least one power management unit, in the function test stage,
wherein the monitor switch circuit comprises at least one sub-switch respectively coupled between the at least one power management unit and the voltage monitor circuit.

19. The voltage calibration method of claim 15, further comprising:
receiving, by at least one management sub-unit, the at least one output voltage from the at least one power management unit respectively, in the function test stage,
wherein the at least one management sub-unit is coupled to the voltage monitor circuit and the at least one power management unit.

20. The voltage calibration method of claim 19, wherein the semiconductor package structure further comprises a second chip, wherein at least one of the at least one management sub-unit is arranged in the first chip, and the others of the at least one management sub-unit is arranged in the second chip.
